(19) United States
(12) Patent Application Publication
(10) Pub. No.: US 2024/0321682 A1
(43) Pub. Date: Sep. 26, 2024

(54) HEAT DISSIPATION STRUCTURES

(71) Applicant: SAMSUNG ELECTRONICS CO., LTD., Suwon-si (KR)

(72) Inventors: Jonggyu Lee, Suwon-si (KR); Jaechoon Kim, Suwon-si (KR); Youngjoon Koh, Suwon-si (KR); Taehwan Kim, Suwon-si (KR)

(21) Appl. No.: 18/394,575

(22) Filed: Dec. 22, 2023

(30) Foreign Application Priority Data
Mar. 24, 2023 (KR) 10-2023-0039173
Apr. 28, 2023 (KR) 10-2023-0056636

(51) Int. Cl. H01L 23/427; H01L 23/00; H01L 23/528; H01L 25/10; H10B 80/00

(52) U.S. Cl. CPC H01L 23/473; H01L 23/3677; H01L 23/3733; H01L 23/44; H01L 24/32; H01L 25/18; H10B 80/00; H01L 24/16; H01L 24/73; H01L 2224/16145; H01L 2224/16227; H01L 2224/32245; H01L 2224/73204; H01L 2224/73253; H01L 2924/1431

(57) ABSTRACT

Provided is a semiconductor package including a package substrate, a semiconductor device mounted on the package substrate, and a heat dissipation structure attached onto the semiconductor device, wherein the heat dissipation structure includes a plurality of vapor chambers at different levels in the vertical direction and a plurality of heat pipes extending between the plurality of vapor chambers.

### CROSS-REFERENCE TO RELATED APPLICATIONS

This application is based on and claims priority under 35 U.S.C. § 119 to Korean Patent Application Nos. 10-2023-0039173, filed on Mar. 24, 2023, and 10-2023-0056636, filed on Apr. 28, 2023, in the Korean Intellectual Property Office, the disclosures of which are incorporated by reference herein in their entireties.

### BACKGROUND

Recently, various semiconductor chips have been packaged in one semiconductor package, and the semiconductor chips are electrically connected to each other to operate as one system. However, when an operation of a semiconductor chip is performed, excessive heat may be generated, and this excessive heat may cause the performance of a semiconductor package to deteriorate.

### SUMMARY

Aspects of this disclosure provide heat dissipation structures and semiconductor packages with improved heat dissipation characteristics.

According to an aspect of the disclosure, there is provided a semiconductor package including a package substrate, a semiconductor device mounted on the package substrate, and a heat dissipation structure attached onto the semiconductor device, wherein the heat dissipation structure includes a plurality of vapor chambers at different levels in the vertical direction and a plurality of heat pipes between the plurality of vapor chambers.

According to another aspect of the disclosure, there is provided a semiconductor package including a package substrate, a semiconductor device mounted on the package substrate, and a heat dissipation structure attached onto the semiconductor device, wherein the heat dissipation structure includes a vapor chamber on the semiconductor device and a boiling enhancing layer provided on an outer surface of the vapor chamber and including at least one of a porous structure and a structure having an uneven surface.

According to another aspect of the disclosure, there is provided a heat dissipation structure including a plurality of vapor chambers at different levels in the vertical direction and a plurality of heat pipes between the plurality of vapor chambers.

### BRIEF DESCRIPTION OF THE DRAWINGS

Implementations according to this disclosure will be more clearly understood from the following detailed description taken in conjunction with the accompanying drawings in which:

FIG. 1 is a cross-sectional view illustrating a semiconductor package according to some implementations;

FIG. 2 is a cross-sectional view illustrating a portion of a heat dissipation structure according to some implementations;

FIG. 3 is a cross-sectional view illustrating a portion of a heat dissipation structure according to some implementations;

FIG. 4 is a cross-sectional view illustrating a semiconductor package according to some implementations;

FIG. 5 is a cross-sectional view illustrating a semiconductor package according to some implementations;

FIG. 6 is a cross-sectional view illustrating a semiconductor package according to some implementations;

FIG. 7 is a cross-sectional view illustrating a semiconductor package according to some implementations;

FIG. 8 is a cross-sectional view illustrating a semiconductor package according to some implementations;

FIG. 9 is a cross-sectional view illustrating a semiconductor package according to some implementations;

FIG. 10 is a cross-sectional view illustrating a semiconductor package according to some implementations;

FIG. 11 is a cross-sectional view illustrating a semiconductor package according to some implementations;

FIG. 12 is a cross-sectional view illustrating a semiconductor package according to some implementations; and

FIGS. 13A and 13B are cross-sectional views illustrating a method of manufacturing a semiconductor package, according to some implementations.

### DETAILED DESCRIPTION

Hereinafter, implementations are described in detail with reference to the accompanying drawings. Like reference numerals in the drawings denote like elements, and thus their repetitive description is omitted.

In the specification, the vertical direction is defined as a Z direction, and the horizontal direction is defined as a direction that is perpendicular to the Z direction. A first horizontal direction and a second horizontal direction are defined as directions intersecting with each other. The first horizontal direction is referred to as an X direction, and the second horizontal direction is referred to as a Y direction. The width of a component is referred to as the length of the component in the horizontal direction, the vertical length of the component is referred to as the length of the component in the vertical direction, and the planar area of the component is referred to as the area of the component occupied on an XY plane.

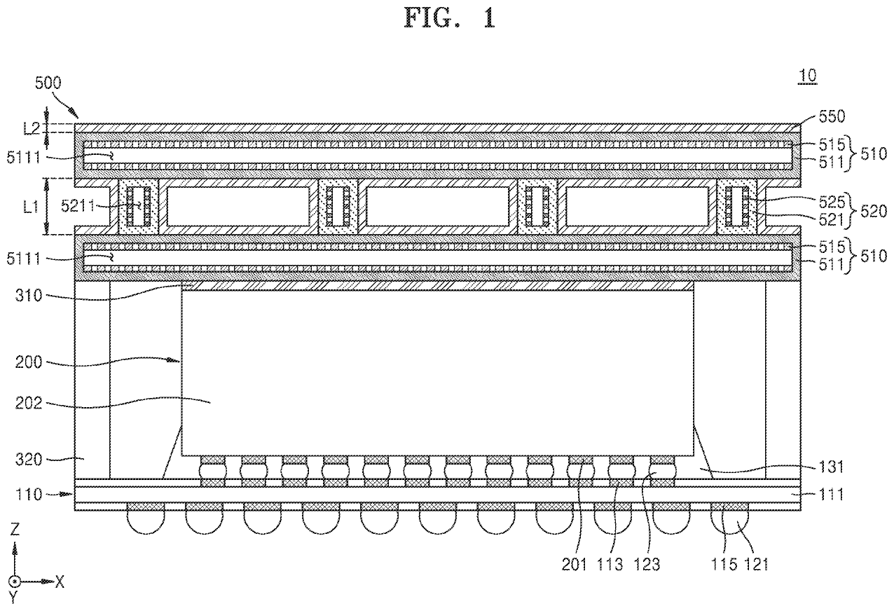

FIG. 1 is a cross-sectional view illustrating a semiconductor package 10 according to some implementations.

Referring to FIG. 1, the semiconductor package 10 includes a package substrate 110, a semiconductor device 200, and a heat dissipation structure 500.

The package substrate 110 may include a printed circuit board, a wafer-based substrate, a ceramic-based substrate, a glass-based substrate, or the like. In some implementations, the package substrate 110 may be a printed circuit board. The package substrate 110 may include a bump pad 115 on the lower surface of an insulating body portion 111 and a conductive pad 113 on the upper surface of the insulating body portion 111. The bump pad 115 may be connected to an external connection terminal 121. The external connection terminal 121 may include, for example, solder. The semiconductor package 10 may be electrically connected via the external connection terminal 121 to a mainboard, a system board, or the like of an external electronic device on which the semiconductor package 10 is mounted.

The semiconductor device 200 may be mounted on the package substrate 110. The semiconductor device 200 may be mounted on the package substrate 110 through a connection bump 123. The semiconductor device 200 may include a semiconductor substrate 202 and a connection pad 201 provided to the bottom of the semiconductor substrate 202. The upper surface of the semiconductor substrate 202 may be an inactive surface of the semiconductor substrate 202, and the lower surface of the semiconductor substrate 202 may be an active surface of the semiconductor substrate 202. The upper surface of the semiconductor substrate 202 may be the upper surface of the semiconductor device 200. The connection bump 123 may electrically and physically connect the conductive pad 113 of the package substrate 110 to the connection pad 201 of the semiconductor device 200. The connection bump 123 may include, for example, solder.

The semiconductor device 200 may include a semiconductor chip. For example, the semiconductor device 200 may include a memory chip and/or a logic chip.

The memory chip may include, for example, a volatile memory chip and/or a nonvolatile memory chip. The volatile memory chip may include, for example, dynamic random access memory (DRAM), static RAM (SRAM), or thyristor RAM (TRAM). The nonvolatile memory chip may include, for example, flash memory, magnetic RAM (MRAM), spin-transfer torque MRAM (STT-MRAM), ferroelectric RAM (FRAM), phase change RAM (PRAM), or resistive RAM (RRAM). For example, the memory chip may include a high bandwidth memory (HBM) chip.

The logic chip may include an application processor (AP), a microprocessor, a central processing unit (CPU), a controller, and/or an application specific integrated circuit (ASIC).

An underfill layer 131 is between the semiconductor device 200 and the package substrate 110. The underfill layer 131 may fill the gap between the semiconductor device 200 and the package substrate 110 and surround connection bumps 123 provided between the semiconductor device 200 and the package substrate 110. The underfill layer 131 may include, for example, an epoxy resin. In some implementations, the underfill layer 131 may be formed of a non-conductive film (NCF).

The heat dissipation structure 500 is thermally and physically coupled to the semiconductor device 200 that is a heat source. The heat dissipation structure 500 may be attached to the upper surface of the semiconductor device 200 through a first thermally conductive adhesive layer 310. The first thermally conductive adhesive layer 310 may be between the heat dissipation structure 500 and the semiconductor device 200 and conformally extend along the upper surface of the semiconductor device 200. The first thermally conductive adhesive layer 310 may be thermally conductive and electrically non-conductive. The first thermally conductive adhesive layer 310 may include a resin layer containing various kinds of fillers. The first thermally conductive adhesive layer 310 may include a thermal interface material (TIM) layer.

The heat dissipation structure 500 includes a plurality of vapor chambers 510 stacked in the vertical direction (the Z direction) and a plurality of heat pipes 520 extending between the plurality of vapor chambers 510.

The plurality of vapor chambers 510 may be at different vertical levels and have a multilayer structure. The planar area and the horizontal width of each vapor chamber 510 may be greater than the planar area and the horizontal width of the semiconductor device 200, respectively. The lowermost vapor chamber 510 among the plurality of vapor chambers 510 may cover the upper surface of the semiconductor device 200. Although FIG. 1 shows that the heat dissipation structure 500 includes two vapor chambers 510 at different vertical levels, the heat dissipation structure 500 is not limited thereto and may include three or more vapor chambers 510 at different vertical levels.

Each vapor chamber 510 cools down a heat source (e.g., the semiconductor device 200) through the phase change in a working fluid. In the vapor chamber 510, the working fluid in a liquid phase changes to a gas phase by evaporating through heat exchange with a heat source. The working fluid in the gas phase flows in the vapor chamber 510 according to a pressure gradient formed in a chamber body 511 and changes to the liquid phase by condensing through heat exchange with a cold wall surface of the vapor chamber 510. Through the phase change of the working fluid, the heat of the heat source may be discharged to the outside of the semiconductor package 10. The working fluid may be a coolant of which the phase changes within a working temperature range of the semiconductor package 10. The working fluid may include, for example, water, ethylene glycol, silicone oil, mineral oil, liquid Teflon, or a mixture formed by a combination thereof.

Each vapor chamber 510 includes the chamber body 511 providing an internal space 5111 in which the working fluid flows and a first wick structure 515 provided inside the chamber body 511.

The chamber body 511 may have a solid shape, such as a rectangular parallelepiped. The chamber body 511 may include a lower wall, an upper wall above the lower wall, and sidewalls extending between the lower wall and the upper wall. The internal space 5111 of the chamber body 511 may be defined by the lower wall, the upper wall, and the sidewalls of the chamber body 511. The lower wall and the upper wall of the chamber body 511 may have a flat plate shape and be parallel to each other. A material of the chamber body 511 may include a metal, such as copper (Cu), aluminum (Al), or stainless steel (SUS).

The first wick structure 515 extends along the inner wall surface of the chamber body 511. The first wick structure 515 may be attached to at least one of the inner wall surface of the lower wall of the chamber body 511, the inner wall surface of the upper wall of the chamber body 511, and the inner wall surfaces of the sidewalls of the chamber body 511. The first wick structure 515 may generate a capillary force for moving the working fluid in the liquid phase toward the heat source. The first wick structure 515 may include, for example, a groove pattern as a structure for generating the capillary force. The first wick structure 515 may include a metal or a metal powder pellet. For example, the first wick structure 515 may include Cu or Al. In the chamber body 511, the working fluid in the liquid phase may move toward the heat source by gravity or the capillary force of the first wick structure 515.

The lowermost vapor chamber 510 may further extend outward from a side surface of the semiconductor device 200 and be supported by a support structure 320 attached onto a border portion of the package substrate 110. A material of the support structure 320 may include a metal, such as Cu, Al, or SUS. In some implementations, the support structure 320 may be integrated with the chamber body 511 of the lowermost vapor chamber 510, and the support structure 320 and the chamber body 511 of the lowermost vapor chamber 510 may include the same material.

The plurality of heat pipes 520 extend between the plurality of vapor chambers 510. The plurality of heat pipes 520 may be between two vapor chambers 510 neighboring in the vertical direction (the Z direction) among the plurality of vapor chambers 510. Between two neighboring vapor chambers 510, the top of a heat pipe 520 may be coupled to an upper vapor chamber 510 and the bottom of the heat pipe 520 may be coupled to a lower vapor chamber 510. For example, a heat pipe 520 may be coupled to corresponding vapor chambers 510 through an adhesive layer or a fastening member (e.g., a bolt).

Each heat pipe 520 transfers heat between the plurality of vapor chambers 510. A vertical height L1 of each heat pipe 520 may be several mm to hundreds of mm. The plurality of heat pipes 520 may have the same vertical height L1. The distance between the plurality of vapor chambers 510 in the vertical direction (the Z direction) may be defined by the vertical height L1 of the plurality of heat pipes 520 and may be several mm to hundreds of mm.

Each heat pipe 520 may transfer heat from a high-temperature portion to a low-temperature portion through the phase change of the working fluid. In each heat pipe 520, the working fluid may change to the gas phase by evaporating at a high-temperature portion of the heat pipe 520. The working fluid in the gas phase may flow along an internal space 5211 of the heat pipe 520 toward a low-temperature portion of the heat pipe 520 and change to a liquid phase by condensing at the low-temperature portion of the heat pipe 520. For example, when a lower vapor chamber 510 at a relatively high temperature is thermally coupled to an upper vapor chamber 510 at a relatively low temperature through heat pipes 520, the heat pipes 520 may transfer heat from the lower vapor chamber 510 to the upper vapor chamber 510. The working fluid may be a coolant of which the phase changes within the working temperature range of the semiconductor package 10. The working fluid may include, for example, water, ethylene glycol, silicone oil, mineral oil, liquid Teflon, or a mixture formed by a combination thereof.

Each heat pipe 520 includes a pipe body 521 providing the internal space 5211 in which the working fluid flows and a second wick structure 525 provided inside the pipe body 521.

The pipe body 521 may have a pillar shape extending between two neighboring vapor chamber 510 among the plurality of vapor chambers 510. A material of the pipe body 521 may include a metal, such as Cu, Al, or SUS. In some implementations, a material composition of the pipe body 521 may be the same as a material composition of the chamber body 511. In some implementations, the material composition of the pipe body 521 may be different from the material composition of the chamber body 511.

The second wick structure 525 is attached to the inner wall surface of the pipe body 521 and extends along the inner wall surface of the pipe body 521. The second wick structure 525 may generate a capillary force for moving the working fluid in the liquid phase toward a hot spot in the pipe body 521. The second wick structure 525 may include, for example, a groove pattern as a structure for generating the capillary force. The second wick structure 525 may include a metal or a metal powder pellet. For example, the second wick structure 525 may include Cu or Al. In the pipe body 521, the working fluid in the liquid phase may move toward a hot spot in the pipe body 521 by gravity or the capillary force of the second wick structure 525.

In some implementations, the heat dissipation structure 500 may cool down the semiconductor device 200 by immersion cooling. The semiconductor package 10 having the heat dissipation structure 500 may be immersed in an external cooling fluid and cooled down through heat exchange between the external cooling fluid and the heat dissipation structure 500. The external cooling fluid may be electrically non-conductive. In the proximity of the outer surface of the heat dissipation structure 500, the external cooling fluid may boil and condense such that heat of the heat dissipation structure 500 is transferred to the external cooling fluid by boiling heat transfer.

According to some implementations, because the heat dissipation structure 500 includes vapor chambers 510 of a multilayer structure, which are stacked through heat pipes 520, a heat spreading characteristic of the heat dissipation structure 500 may be improved, thereby resulting in improvement of the uniformity of the surface temperature of the heat dissipation structure 500 and improvement of boiling heat transfer efficiency using the external cooling fluid. Accordingly, the heat dissipation characteristic and reliability of the semiconductor package 10 including the heat dissipation structure 500 may be improved.

In some implementations, the heat dissipation structure 500 may include a boiling enhancing layer 550 on at least a portion of an outer surface of each vapor chamber 510 and/or at least a portion of an outer surface of each heat pipe 520. The boiling enhancing layer 550 may enhance a boiling heat transfer characteristic between the external cooling fluid and the heat dissipation structure 500. The boiling enhancing layer 550 may have a low contact angle with respect to the external cooling fluid. For example, a material of the boiling enhancing layer 550 may include, for example, Cu, nickel (Ni), Al, and/or silicon (Si).

The boiling enhancing layer 550 may include at least one of a porous structure having micro pores and a surface roughness enhancing structure having a non-planar (uneven) surface.

The porous structure of the boiling enhancing layer 550 may include micro pores or micro holes. The micro pores of the porous structure may be provided as a space in which the external cooling fluid stays or bubbles of the external cooling fluid grow, to enhance boiling heat transfer between the external cooling fluid and the heat dissipation structure 500. For example, the porous structure may be formed by attaching a porous member to the chamber body 511 of the vapor chamber 510 and/or the pipe body 521 of the heat pipe 520 by using a thermally conductive adhesive layer (e.g., a solder layer), formed on the chamber body 511 of the vapor chamber 510 and/or the pipe body 521 of the heat pipe 520 through a sintering process or a deposition process, or formed by directly processing the chamber body 511 of the vapor chamber 510 and/or the pipe body 521 of the heat pipe 520. For example, the porous structure of the boiling enhancing layer 550 may have an inverse opal structure, a mesh structure, or a foam structure.

In some implementations, the boiling enhancing layer 550 may include the surface roughness enhancing structure to increase the surface roughness of the outermost surface of the heat dissipation structure 500 in direct contact with the external cooling fluid. The surface roughness enhancing structure may provide a non-planar surface. The surface roughness enhancing structure of the heat dissipation structure 500 may increase a heat exchange area between the heat dissipation structure 500 and the external cooling fluid, thereby improving heat exchange between the heat dissipation structure 500 and the external cooling fluid. The surface roughness enhancing structure may be formed by attaching a member having a non-planar surface to the chamber body 511 of the vapor chamber 510 and/or the pipe body 521 of the heat pipe 520 by using a thermally conductive adhesive layer (e.g., a solder layer), forming a structure having a non-planar surface on the chamber body 511 of the vapor chamber 510 and/or the pipe body 521 of the heat pipe 520 through a sintering process or a deposition process, or directly processing the chamber body 511 of the vapor chamber 510 and/or the pipe body 521 of the heat pipe 520. For example, the surface roughness enhancing structure of the boiling enhancing layer 550 may include a pillar structure, a herring-bone structure, and/or a microchannel structure.

In some implementations, the surface roughness enhancing structure of the boiling enhancing layer 550 may include a plurality of protruding patterns on the chamber body 511 of the vapor chamber 510 and/or the pipe body 521 of the heat pipe 520. The plurality of protruding patterns may be separated from each other to provide a passage or space through which the external cooling fluid flows. Each of the plurality of protruding patterns may have a dot shape or a line shape extending in one direction.

In some implementations, to increase affinity between the heat dissipation structure 500 and the external cooling fluid, oxidation treatment and/or laser surface treatment on the vapor chamber 510 and/or the heat pipe 520 may be performed and the boiling enhancing layer 550 may include a metal oxide layer formed through the oxidation treatment and/or a laser processing layer formed through the laser surface treatment. The metal oxide layer and the laser processing layer may be formed directly on the surface of the chamber body 511 and/or the pipe body 521 or formed on the porous structure or the surface roughness enhancing structure of the boiling enhancing layer 550.

The boiling enhancing layer 550 may conformally extend along the outer surface of the vapor chamber 510 of the heat dissipation structure 500 and/or the outer surface of the heat pipe 520. For example, the boiling enhancing layer 550 may be attached to the outer surfaces of the plurality of vapor chambers 510 and conformally extend along the outer surfaces of the plurality of vapor chambers 510. For example, the boiling enhancing layer 550 may be attached to the outer surfaces of the plurality of heat pipes 520 and conformally extend along the outer surfaces of the plurality of heat pipes 520. In some implementations, a thickness L2 of the boiling enhancing layer 550 may be 1 mm or less. In some implementations, the thickness L2 of the boiling enhancing layer 550 may be several micrometers to 1 mm.

According to some implementations, because the heat dissipation structure 500 includes the boiling enhancing layer 550 capable of enhancing a boiling heat transfer effect, boiling heat transfer efficiency using the external cooling fluid may be improved. Accordingly, the heat dissipation characteristic and reliability of the semiconductor package 10 including the heat dissipation structure 500 may be improved.

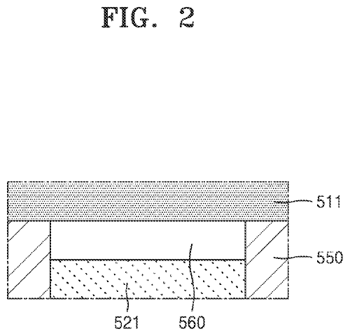

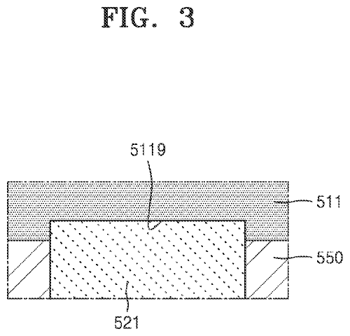

FIGS. 2 and 3 are cross-sectional views illustrating a portion of the heat dissipation structure 500 according to some implementations. Hereinafter, methods of connecting a vapor chamber 510 to a heat pipe 520, according to some implementations of the heat dissipation structure 500, are described with reference to FIGS. 2 and 3.

Referring to FIGS. 1 and 2, the vapor chamber 510 is thermally and physically coupled to the heat pipe 520 through a second thermally conductive adhesive layer 560. Between neighboring vapor chambers 510, the top of each heat pipe 520 may be thermally and physically coupled to an upper vapor chamber 510 through the second thermally conductive adhesive layer 560, and the bottom of each heat pipe 520 may be thermally and physically coupled to a lower vapor chamber 510 through the second thermally conductive adhesive layer 560. The second thermally conductive adhesive layer 560 may be provided to the interface between the chamber body 511 of the vapor chamber 510 and the pipe body 521 of the heat pipe 520. For example, the second thermally conductive adhesive layer 560 may include solder. For example, the second thermally conductive adhesive layer 560 may include a TIM layer.

Referring to FIGS. 1 and 3, the chamber body 511 of the vapor chamber 510 may have a mounting groove 5119 in which the pipe body 521 of the heat pipe 520 is inserted and fixed. Between neighboring vapor chambers 510, the top of each heat pipe 520 may be inserted into and fixed to the mounting groove 5119 of the chamber body 511 of an upper vapor chamber 510, and the bottom of each heat pipe 520 may be inserted into and fixed to the mounting groove 5119 of the chamber body 511 of a lower vapor chamber 510. In some implementations, a thermally conductive adhesive layer, such as solder or a TIM layer, for bonding the chamber body 511 of the vapor chamber 510 with the pipe body 521 of the heat pipe 520 may be at the interface between the chamber body 511 of the vapor chamber 510 and the pipe body 521 of the heat pipe 520.

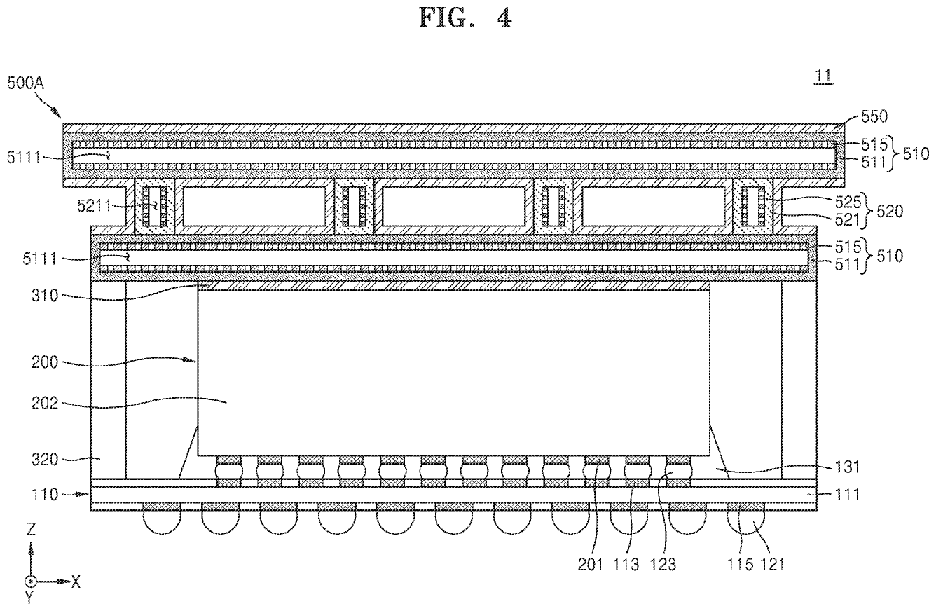

FIG. 4 is a cross-sectional view illustrating a semiconductor package 11 according to some implementations. Hereinafter, the semiconductor package 11 of FIG. 4 is described based on the differences from the semiconductor package 10 described with reference to FIG. 1.

Referring to FIG. 4, in a heat dissipation structure 500A of the semiconductor package 11, the plurality of vapor chambers 510 have different horizontal widths and/or planar areas. In some implementations, in the plurality of vapor chambers 510 at different vertical levels, the horizontal width of an upper vapor chamber 510 may be greater than the horizontal width of the lowermost vapor chamber 510 attached to the semiconductor device 200, and the upper vapor chamber 510 may further extend outward from a side portion of the lowermost vapor chamber 510. When the lowermost vapor chamber 510 has a first horizontal width, a vapor chamber 510 at an upper side than the lowermost vapor chamber 510 may have a second horizontal width that is greater than the first horizontal width of the lowermost vapor chamber 510.

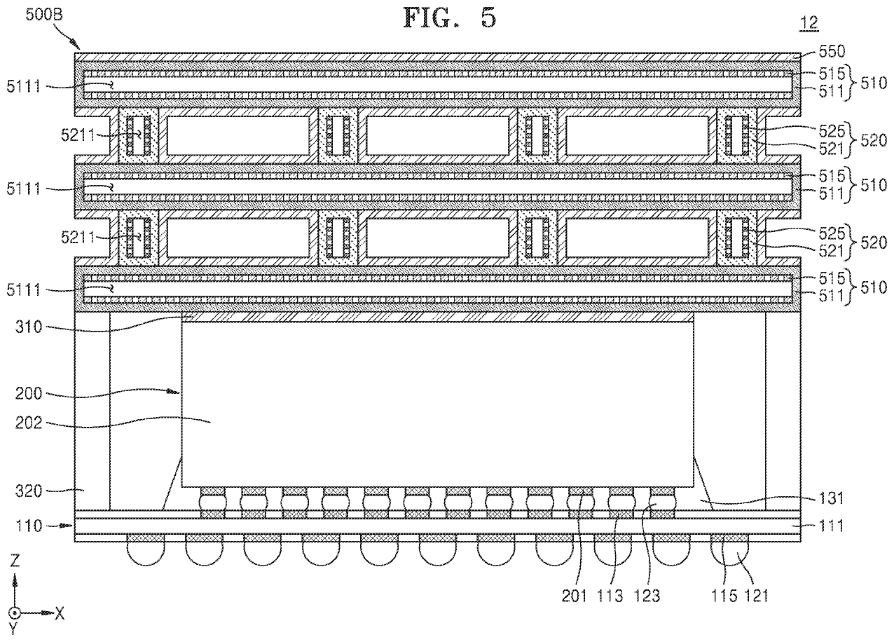

FIG. 5 is a cross-sectional view illustrating a semiconductor package 12 according to some implementations. Hereinafter, the semiconductor package 12 of FIG. 5 is described based on the differences from the semiconductor package 10 described with reference to FIG. 1.

Referring to FIG. 5, a heat dissipation structure 500B of the semiconductor package 12 includes three vapor chambers 510 at different vertical levels. Two neighboring vapor chambers 510 among the three vapor chambers 510 may be thermally and physically coupled through the plurality of heat pipes 520. In some implementations, the three vapor chambers 510 may have the same horizontal width or planar area. In some implementations, the horizontal width or planar area of each of the vapor chambers 510 provided at upper sides may be greater than the horizontal width or planar area of the lowermost vapor chamber 510.

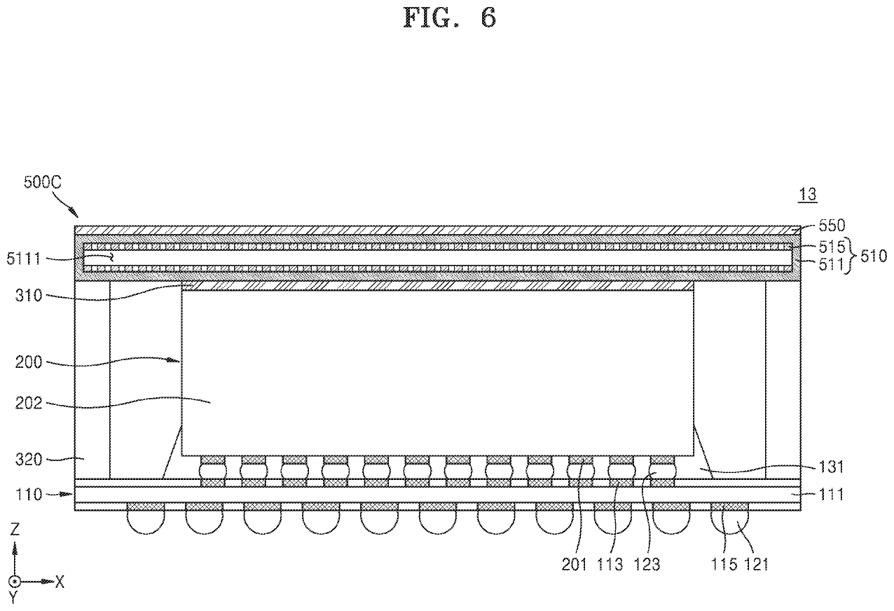

FIG. 6 is a cross-sectional view illustrating a semiconductor package 13 according to some implementations. Hereinafter, the semiconductor package 13 of FIG. 6 is described based on the differences from the semiconductor package 10 described with reference to FIG. 1.

Referring to FIG. 6, a heat dissipation structure 500C of the semiconductor package 13 includes a single-layer vapor chamber 510 and the boiling enhancing layer 550 extending along the surface of the chamber body 511 of the vapor chamber 510. The boiling enhancing layer 550 may be a porous structure and may be formed through a deposition process on the surface of the chamber body 511 or a sintering process using metal powder. In some implementations, in the boiling enhancing layer 550, the sizes of pores may vary for each region. For example, in the boiling enhancing layer 550, the sizes of pores in a region vertically overlapping the semiconductor device 200 may be greater than the sizes of pores in a region vertically not overlapping the semiconductor device 200.

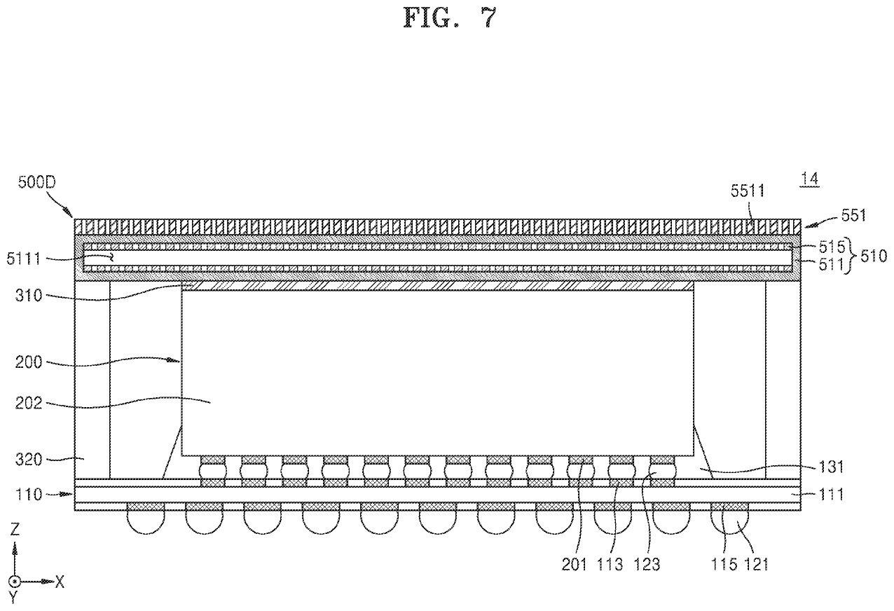

FIG. 7 is a cross-sectional view illustrating a semiconductor package 14 according to some implementations. Hereinafter, the semiconductor package 14 of FIG. 7 is described based on the differences from the semiconductor package 10 described with reference to FIG. 1.

Referring to FIG. 7, in a heat dissipation structure 500D of the semiconductor package 14, a boiling enhancing layer 551 includes a plurality of protruding patterns 5511 provided on the surface of the chamber body 511 of the vapor chamber 510. The plurality of protruding patterns 5511 of the boiling enhancing layer 551 may increase the surface roughness of the outer surface of the heat dissipation structure 500D, and this increase in the surface roughness of the outer surface of the heat dissipation structure 500D may cause an increase in a heat exchange area between the external cooling fluid and the heat dissipation structure 500D. In addition, a space formed by separating the plurality of protruding patterns 5511 from each other may be provided as a space in which the external cooling fluid stays or bubbles grow. In some implementations, the plurality of protruding patterns 5511 may be formed through physical processing on the chamber body 511 of the vapor chamber 510, and in this case, a material of the plurality of protruding patterns 5511 may be the same as a material of the chamber body 511.

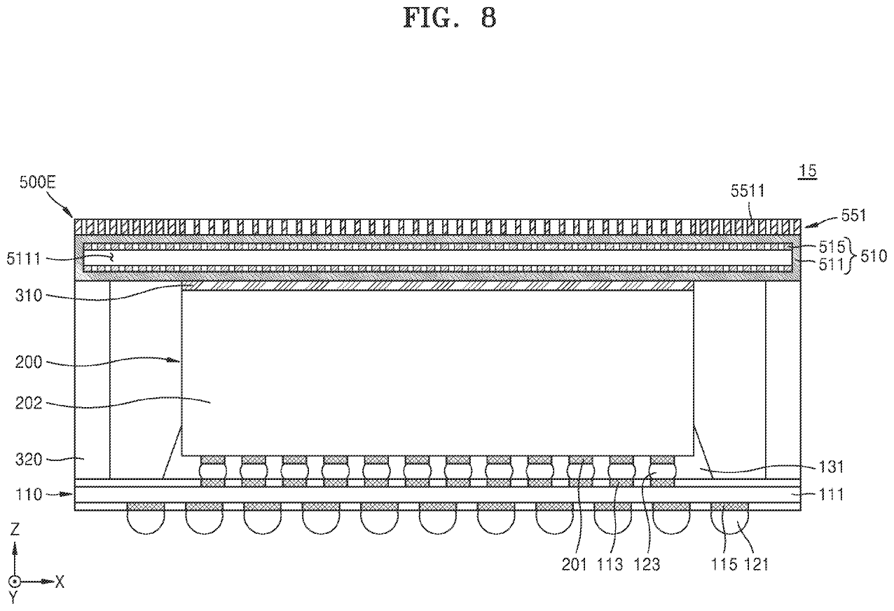

FIG. 8 is a cross-sectional view illustrating a semiconductor package 15 according to some implementations. Hereinafter, the semiconductor package 15 of FIG. 8 is described based on the differences from the semiconductor package 10 described with reference to FIG. 1.

Referring to FIG. 8, in a heat dissipation structure 500E of the semiconductor package 15, the boiling enhancing layer 551 includes the plurality of protruding patterns 5511 provided on the surface of the chamber body 511 of the vapor chamber 510, and the shapes, the dimensions, and/or the arrangements of the plurality of protruding patterns 5511 vary for each region in the boiling enhancing layer 551.

For example, when the boiling enhancing layer 551 includes a central region vertically overlapping the semiconductor device 200 and a border region vertically not overlapping the semiconductor device 200, protrusion patterns 5511 (sometimes referred to as “protruding patterns”) in the central region of the boiling enhancing layer 551 and protrusion patterns 5511 in the border region of the boiling enhancing layer 551 may have different shapes, dimensions, and/or arrangements. For example, the gap between the protrusion patterns 5511 in the central region of the boiling enhancing layer 551 may be greater than the gap between the protrusion patterns 5511 in the border region of the boiling enhancing layer 551. For example, the dimension (e.g., the horizontal width) of the protrusion patterns 5511 in the central region of the boiling enhancing layer 551 may be less than the dimension (e.g., the horizontal width) of the protrusion patterns 5511 in the border region of the boiling enhancing layer 551.

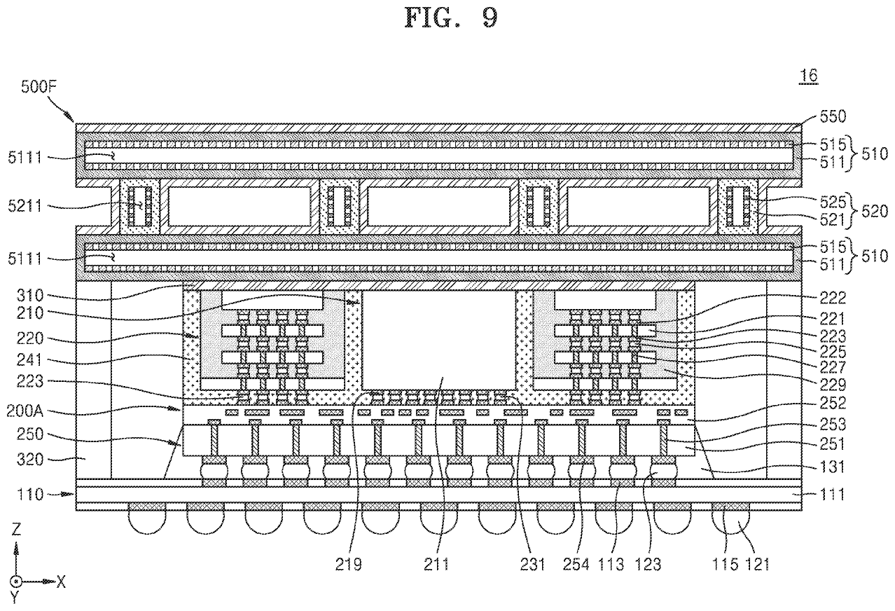

FIG. 9 is a cross-sectional view illustrating a semiconductor package 16 according to some implementations. Hereinafter, the semiconductor package 16 of FIG. 9 is described based on the differences from the semiconductor package 10 described with reference to FIG. 1.

Referring to FIG. 9, in the semiconductor package 16, a semiconductor device 200A includes an interposer substrate 250, a first semiconductor chip 210, a second semiconductor chip 220, and a molding layer 241. Although FIG. 9 shows that a heat dissipation structure 500F attached onto the semiconductor device 200A is the heat dissipation structure 500 shown in FIG. 1, the heat dissipation structure 500F is not limited thereto and may correspond to any one of the heat dissipation structures 500A, 500B, 500C, 500D, and 500E shown in FIGS. 4 to 8.

The interposer substrate 250 may be mounted on the package substrate 110 through the connection bump 123. The interposer substrate 250 may include an Si substrate 251 and a redistribution structure 252 on the Si substrate 251. The interposer substrate 250 may further include a through electrode 253 electrically connected to a conductive redistribution pattern in the redistribution structure 252 and penetrating into the Si substrate 251 and a connection pad 254 beneath the Si substrate 251. The connection pad 254 may be electrically connected to the through electrode 253 and the connection bump 123.

The first semiconductor chip 210 and the second semiconductor chip 220 are mounted on the interposer substrate 250 and are separated from each other in the lateral direction. The first semiconductor chip 210 may perform a different function from that of the second semiconductor chip 220. Each of the first semiconductor chip 210 and the second semiconductor chip 220 may exchange a signal with an external device through the interposer substrate 250, and the first semiconductor chip 210 may be electrically connected to the second semiconductor chip 220 through the interposer substrate 250. For example, the second semiconductor chip 220 may be at each of one side and the other side of the first semiconductor chip 210. However, the number and arrangement of semiconductor chips shown in FIG. 9 are only illustrative, and the number and arrangement of semiconductor chips may be modified according to circumstances.

In some implementations, the power consumption of the first semiconductor chip 210 may be greater than the power consumption of the second semiconductor chip 220, and a heat generation rate while operating the first semiconductor chip 210 may be greater than a heat generation rate while operating the second semiconductor chip 220. In some implementations, the first semiconductor chip 210 may include a logic chip and the second semiconductor chip 220 may include a memory chip. For example, the logic chip may include an ASIC chip and the second semiconductor chip 220 may include an HBM chip.

The first semiconductor chip 210 may include a first semiconductor substrate 211, a first chip pad 219, and a first connection member 231.

The first semiconductor substrate 211 may include an active surface and an inactive surface that are opposite to each other. Herein, the inactive surface of the first semiconductor substrate 211 may be the upper surface of the first semiconductor chip 210, which is exposed through the molding layer 241 and in contact with the first thermally conductive adhesive layer 310. The upper surface of the first semiconductor chip 210 may be a plane perpendicular to the vertical direction (the Z direction).

The first semiconductor substrate 211 may be an Si wafer including, for example, crystalline Si, polycrystalline Si, or amorphous Si. Alternatively, the first semiconductor substrate 211 may include a semiconductor element, such as germanium (Ge), or a compound semiconductor, such as silicon carbide (SiC), gallium arsenide (GaAs), indium arsenide (InAs), or indium phosphide (InP).

In addition, the first semiconductor substrate 211 may have a silicon on insulator (SOI) structure. For example, the first semiconductor substrate 211 may include a buried oxide (BOX) layer. In some implementations, the first semiconductor substrate 211 may include a conductive region, e.g., an impurity-doped well or an impurity-doped structure. In addition, the first semiconductor substrate 211 may have various device isolation structures, such as a shallow trench isolation (STI) structure.

A semiconductor wiring layer may be on the active surface of the first semiconductor substrate 211. A wiring pattern of the semiconductor wiring layer may be electrically connected to the first chip pad 219 provided to the lower surface of the first semiconductor chip 210. The first chip pad 219 may include at least one of, for example, Al, Cu, Ni, tungsten (W), platinum (Pt), and gold (Au). The first connection member 231 may include, for example, solder. The first semiconductor chip 210 may be mounted on the redistribution structure 252 through the first connection member 231.

The second semiconductor chip 220 may include a second semiconductor substrate 221, a second upper connection pad 222, a second lower connection pad 223, a second connection member 225, a through electrode 227, and an internal molding layer 229.

The second semiconductor chip 220 may include a plurality of slices, and each of the plurality of slices may include the second semiconductor substrate 221. The plurality of second semiconductor substrates 221 may be stacked in the vertical direction (the Z direction) to constitute a chip stack. The plurality of second semiconductor substrates 221 may be substantially the same as each other. That is, the second semiconductor chip 220 may have a stacked structure in which the plurality of slices operate as respective memory chips and mutual data aggregation is possible.

Each of the plurality of second semiconductor substrates 221 may have an active surface and an inactive surface that are opposite to each other. For example, the inactive surface of the uppermost second semiconductor substrate 221 among the plurality of second semiconductor substrates 221 may be the upper surface of the second semiconductor chip 220 exposed through the molding layer 241. Each of the second semiconductor substrates 221 remaining by excluding the uppermost second semiconductor substrate 221 from the plurality of second semiconductor substrates 221 may include the through electrode 227. The through electrode 227 may be, for example, a through silicon via (TSV).

The second upper connection pad 222 may be connected to the top of the through electrode 227, and the second lower connection pad 223 may be connected to the bottom of the through electrode 227. In addition, the second lower connection pad 223 may be provided to the active surface of the second semiconductor substrate 221 and electrically connected to a semiconductor wiring layer including a wiring pattern.

The second connection member 225 may be between two second semiconductor substrates 221 neighboring in the vertical direction (the Z direction). In addition, the second connection member 225 in contact with the lowermost second semiconductor substrate 221 among the plurality of second semiconductor substrates 221 may electrically connect the second semiconductor chip 220 to the interposer substrate 250. The second connection member 225 may be a solder ball attached to the second lower connection pad 223.

The internal molding layer 229 may surround the plurality of second semiconductor substrates 221 and fill the gaps between every two neighboring second semiconductor substrates 221 in the vertical direction (the Z direction) among the second semiconductor substrates 221. The internal molding layer 229 may not cover the upper surface of the uppermost second semiconductor substrate 221. The internal molding layer 229 may include, for example, an epoxy molding compound.

The molding layer 241 may be on the interposer substrate 250 and surround the first and second semiconductor chips 210 and 220. The molding layer 241 may not cover the upper surface of the first semiconductor chip 210 and the upper surface of the second semiconductor chip 220. In some implementations, the upper surface of the molding layer 241 may be coplanar with the upper surface of the first semiconductor chip 210 and the upper surface of the second semiconductor chip 220. The first thermally conductive adhesive layer 310 may extend along the upper surface of the molding layer 241, the upper surface of the first semiconductor chip 210, and the upper surface of the second semiconductor chip 220, which are coplanar with each other.

The molding layer 241 may protect the first and second semiconductor chips 210 and 220 from an external environment. To perform this function, the molding layer 241 may include an epoxy molding compound or a resin. In addition, the molding layer 241 may be formed by a process, such as compression molding, lamination, or screen printing.

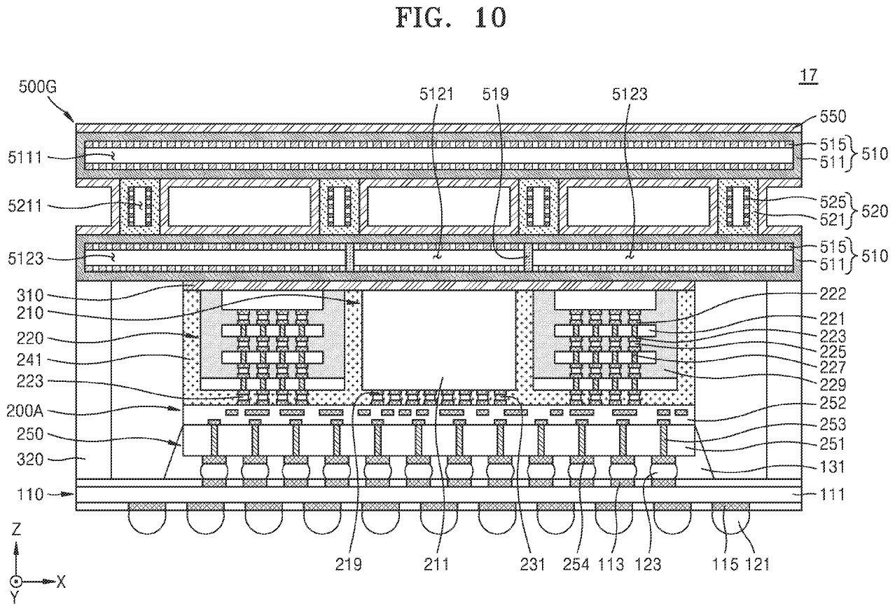

FIG. 10 is a cross-sectional view illustrating a semiconductor package 17 according to some implementations. Hereinafter, the semiconductor package 17 of FIG. 10 is described based on the differences from the semiconductor package 16 described with reference to FIG. 9.

Referring to FIG. 10, in a heat dissipation structure 500G of the semiconductor package 17, the lowermost vapor chamber 510 includes isolation partitions 519 provided inside the chamber body 511. The isolation partitions 519 divide the internal space 5111 (see FIG. 1) of the chamber body 511 into a plurality of sub-spaces. In the chamber body 511, the isolation partitions 519 block flow of the working fluid among the plurality of sub-spaces to thermally isolate among the plurality of sub-spaces. For example, an isolation partition 519 may isolate between a first sub-space 5121 vertically overlapping the first semiconductor chip 210 and a second sub-space 5123 vertically overlapping the second semiconductor chip 220. The first sub-space 5121 may be associated with heat dissipation of the first semiconductor chip 210, and the second sub-space 5123 may be associated with heat dissipation of the second semiconductor chip 220. The isolation partition 519 may thermally isolate between the first sub-space 5121 and the second sub-space 5123, thereby reducing thermal crosstalk between the first semiconductor chip 210 and the second semiconductor chip 220.

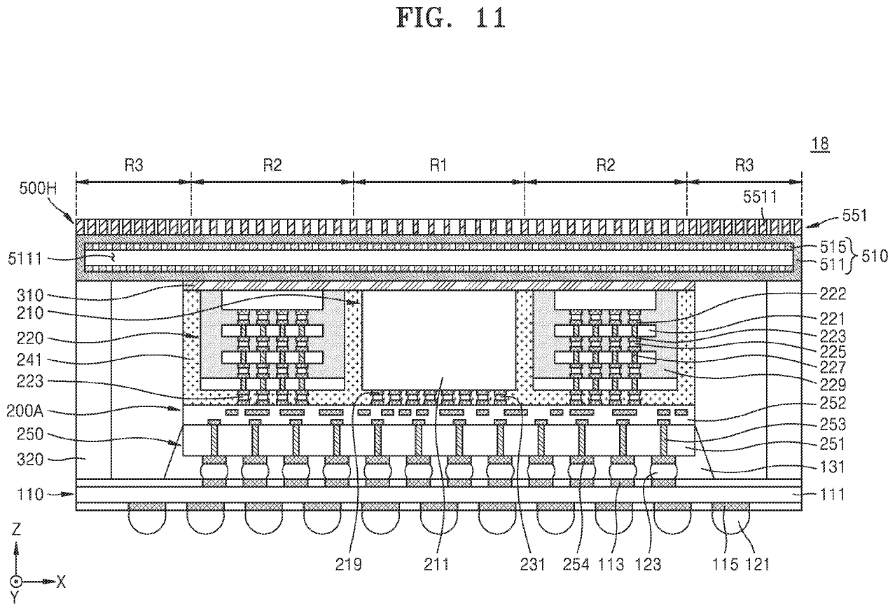

FIG. 11 is a cross-sectional view illustrating a semiconductor package 18 according to some implementations. Hereinafter, the semiconductor package 18 of FIG. 11 is described based on the differences from the semiconductor package 16 described with reference to FIG. 9.

Referring to FIG. 11, in a heat dissipation structure 500H of the semiconductor package 18, the boiling enhancing layer 551 includes the plurality of protruding patterns 5511 provided on the surface of the chamber body 511 of the vapor chamber 510, and the shapes, the dimensions, and/or the arrangements of the plurality of protruding patterns 5511 vary for each region in the boiling enhancing layer 551.

For example, when the boiling enhancing layer 551 includes a first region R1 vertically overlapping the first semiconductor chip 210, a second region R2 vertically overlapping the second semiconductor chip 220, and a third region R3 not vertically overlapping the first and second semiconductor chips 210 and 220, protrusion patterns 5511 in the first region R1 of the boiling enhancing layer 551, protrusion patterns 5511 in the second region R2 of the boiling enhancing layer 551, and protrusion patterns 5511 in the third region R3 of the boiling enhancing layer 551 may have different shapes, dimensions, and/or arrangements. For example, the gap between the protrusion patterns 5511 in the first region R1 of the boiling enhancing layer 551 may be greater than the gap between the protrusion patterns 5511 in the second region R2 of the boiling enhancing layer 551. For example, the dimension (e.g., the horizontal width) of the protrusion patterns 5511 in the first region R1 of the boiling enhancing layer 551 may be less than the dimension (e.g., the horizontal width) of the protrusion patterns 5511 in the second region R2 of the boiling enhancing layer 551.

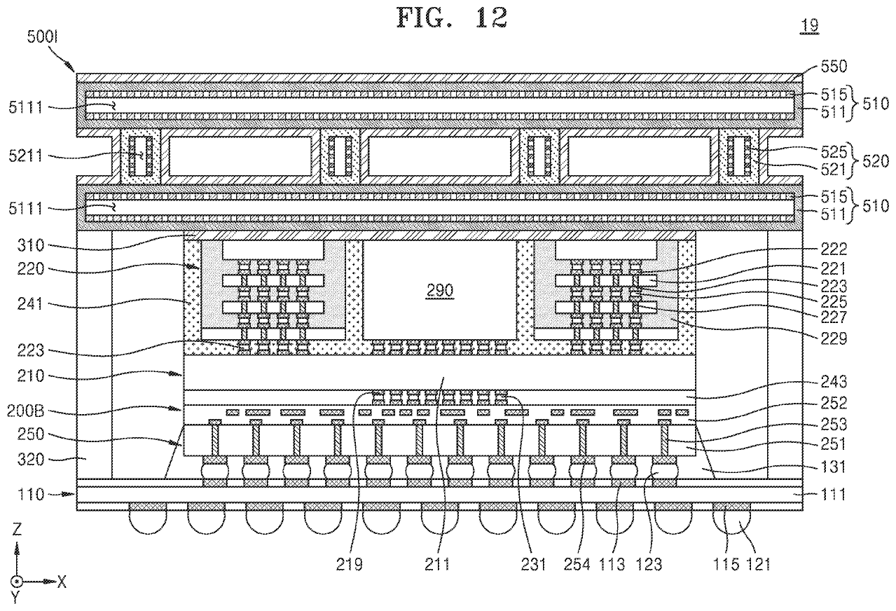

FIG. 12 is a cross-sectional view illustrating a semiconductor package 19 according to some implementations. Hereinafter, the semiconductor package 19 of FIG. 12 is described based on the differences from the semiconductor package 16 described with reference to FIG. 9.

Referring to FIG. 12, in the semiconductor package 19, a semiconductor device 200B includes the interposer substrate 250, the first semiconductor chip 210 mounted on the interposer substrate 250, the second semiconductor chip 220 mounted on the first semiconductor chip 210, and the molding layer 241. Although FIG. 12 shows that a heat dissipation structure 500I attached onto the semiconductor device 200B is the heat dissipation structure 500 shown in FIG. 1, the heat dissipation structure 500I is not limited thereto and may correspond to any one of the heat dissipation structures 500A, 500B, 500C, 500D, and 500E shown in FIGS. 4 to 8.

The first semiconductor chip 210 may have the same or similar planar area as or to that of the interposer substrate 250. The first semiconductor chip 210 may be mounted on the interposer substrate 250 through the first connection member 231. A gap-fill insulating layer 243 surrounding the first connection member 231 may be between the first semiconductor chip 210 and the interposer substrate 250.

The second semiconductor chip 220 may be mounted on the first semiconductor chip 210 through a connection member 233. The connection member 233 may include, for example, solder.

In some implementations, two second semiconductor chips 220 separated from each other in the first horizontal direction (the X direction) may be on the first semiconductor chip 210, and a dummy semiconductor chip 290 may be between the two second semiconductor chips 220. The dummy semiconductor chip 290 may include the Si substrate 251. The upper surface of the dummy semiconductor chip 290 may not be covered by the molding layer 241. In some implementations, the upper surface of the dummy semiconductor chip 290 may be coplanar with the upper surface of the molding layer 241 and the upper surface of the second semiconductor chip 220. The first thermally conductive adhesive layer 310 may extend along the upper surface of the dummy semiconductor chip 290, the upper surface of the molding layer 241, and the upper surface of the second semiconductor chip 220.

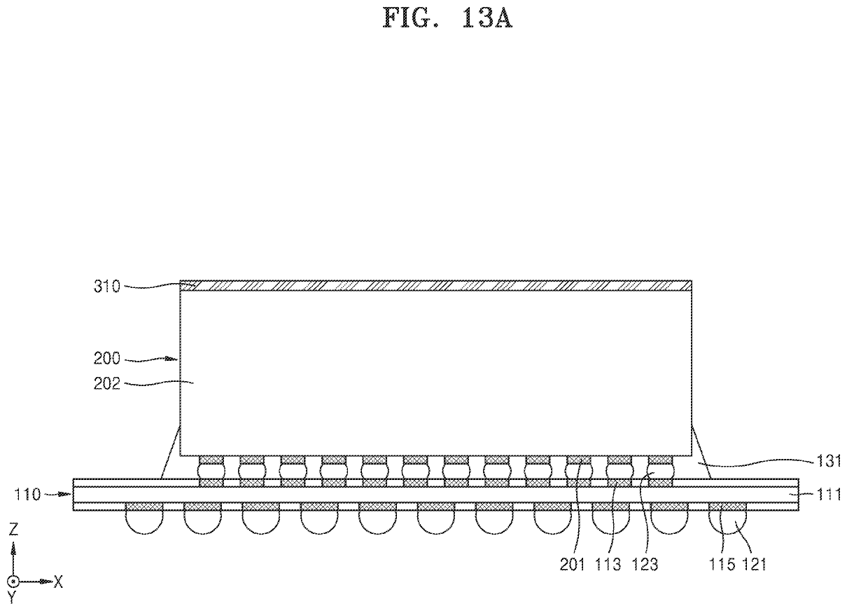

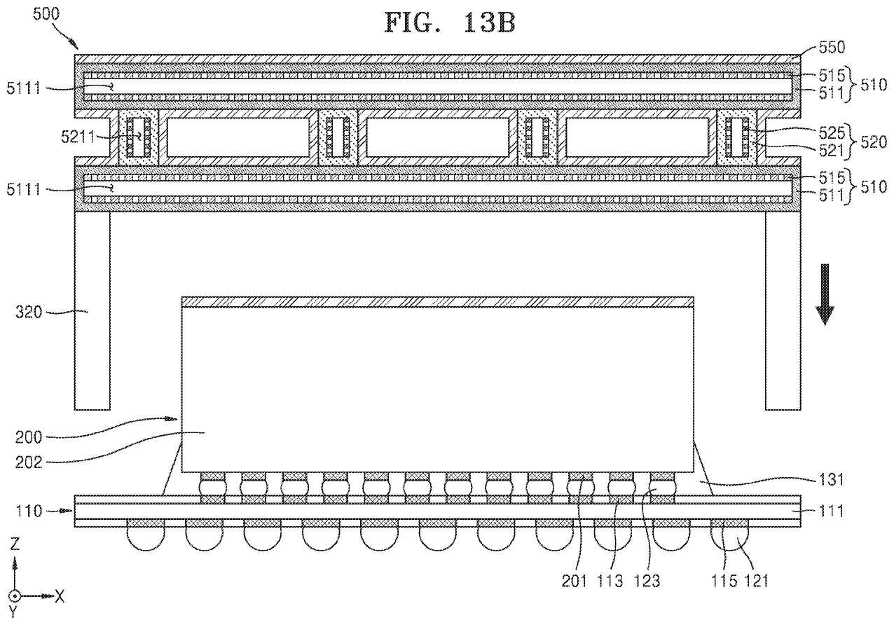

FIGS. 13A and 13B are cross-sectional views illustrating a method of manufacturing a semiconductor package, according to some implementations.

Referring to FIG. 13A, the semiconductor device 200 is mounted on the package substrate 110. The semiconductor device 200 may be mounted on the package substrate 110 through the connection bump 123 by a flip chip method. After mounting the semiconductor device 200 on the package substrate 110, an underfill process is performed to form the underfill layer 131 filling the gap between the semiconductor device 200 and the package substrate 110 and form the first thermally conductive adhesive layer 310 covering the upper surface of the semiconductor device 200.

Referring to FIG. 13B, the heat dissipation structure 500 is prepared. The heat dissipation structure 500 may include the plurality of vapor chambers 510 stacked through the plurality of heat pipes 520. The lowermost vapor chamber 510 among the plurality of vapor chambers 510 may include the support structure 320 connected to a border portion of the lower surface of the lowermost vapor chamber 510. For example, the preparing of the heat dissipation structure 500 may include preparing the lowermost vapor chamber 510 to which a boiling enhancing layer 550 (e.g., a first boiling enhancing layer) is attached, coupling the plurality of heat pipes 520 to which other boiling enhancing layers 550 (e.g., second boiling enhancing layers) are attached onto the lowermost vapor chamber 510, and coupling another vapor chamber 510 (e.g., an upper vapor chamber) to which another boiling enhancing layer 550 (e.g., a third boiling enhancing layer) is attached onto the plurality of heat pipes 520. For example, the vapor chamber 510 may be coupled to the heat pipe 520 by using a thermally conductive adhesive layer, such as solder.

After preparing the heat dissipation structure 500, the heat dissipation structure 500 having the support structure 320 is attached onto the semiconductor device 200. The lowermost vapor chamber 510 may be attached to the upper surface of the semiconductor device 200 through the first thermally conductive adhesive layer 310. In addition, the support structure 320 may be attached to a border portion of the package substrate 110. The support structure 320 may be attached to the package substrate 110 by an adhesive.

While this specification contains many specific implementation details, these should not be construed as limitations on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations and even initially be claimed as such, one or more features from a claimed combination can in some cases be excised from the combination, and the claimed combination may be directed to a subcombination or variation of a subcombination.

While some implementations have been particularly shown and described, it will be understood that various changes in form and details may be made therein without departing from the spirit and scope of the following claims.

1. A semiconductor package comprising:
a package substrate;
a semiconductor device mounted on the package substrate; and
a heat dissipation structure attached to the semiconductor device,
wherein the heat dissipation structure comprises
a plurality of vapor chambers at different levels in a vertical direction, and
a plurality of heat pipes between the plurality of vapor chambers.

2. The semiconductor package of claim 1, comprising a first thermally conductive adhesive layer between a lowermost vapor chamber of the plurality of vapor chambers and the semiconductor device.

3. The semiconductor package of claim 1, wherein lengths of the plurality of vapor chambers in a horizontal direction are different from each other.

4. The semiconductor package of claim 1, wherein the plurality of vapor chambers comprise three vapor chambers stacked in the vertical direction, and
wherein two vapor chambers neighboring one another in the vertical direction of the three vapor chambers are connected to one another through corresponding heat pipes of the plurality of heat pipes.

5. The semiconductor package of claim 1, wherein each of the plurality of vapor chambers is coupled to corresponding heat pipes among the plurality of heat pipes by a second thermally conductive adhesive layer.

6. The semiconductor package of claim 5, wherein the second thermally conductive adhesive layer comprises solder.

7. The semiconductor package of claim 1, wherein each vapor chamber of the plurality of vapor chambers comprises a chamber body, and
wherein the chamber body of each vapor chamber has a mounting groove into which a corresponding heat pipe of the plurality of heat pipes is inserted.

8. The semiconductor package of claim 1, wherein each vapor chamber of the plurality of vapor chambers comprises a chamber body providing an internal space in which a first working fluid flows, and
wherein each heat pipe of the plurality of heat pipes comprises a pipe body providing an internal space in which a second working fluid flows.

9. The semiconductor package of claim 1, wherein the heat dissipation structure comprises a porous structure extending along outer surfaces of the plurality of vapor chambers.

10. The semiconductor package of claim 1, wherein the heat dissipation structure comprises a plurality of protruding patterns provided on outer surfaces of the plurality of vapor chambers.

11. The semiconductor package of claim 10, wherein at least one of shapes or dimensions of the plurality of protruding patterns are different for different regions of the heat dissipation structure.

12. The semiconductor package of claim 1, wherein the semiconductor device comprises:
an interposer substrate on the package substrate;
a plurality of semiconductor chips mounted on the interposer substrate and separated from one another in a horizontal direction; and
a molding layer on the interposer substrate and surrounding the plurality of semiconductor chips,
wherein the plurality of semiconductor chips comprise a logic chip and a memory chip.

13. The semiconductor package of claim 12, wherein a lowermost vapor chamber of the plurality of vapor chambers comprises:
a chamber body providing an internal space in which a working fluid flows; and
an isolation partition in the chamber body, the isolation partition dividing the internal space into a plurality of sub-spaces,
wherein the plurality of sub-spaces comprise a first sub-space vertically overlapping the logic chip and a second sub-space vertically overlapping the memory chip.

14. (canceled)

15. A semiconductor package comprising:
a package substrate;
a semiconductor device mounted on the package substrate; and
a heat dissipation structure attached onto the semiconductor device,
wherein the heat dissipation structure comprises
a vapor chamber on the semiconductor device, and
a boiling enhancing layer provided on an outer surface of the vapor chamber and comprising at least one of a porous structure or a structure having an uneven surface.

16. The semiconductor package of claim 15, wherein the vapor chamber is attached to an upper surface of the semiconductor device by a thermally conductive adhesive layer extending along the upper surface of the semiconductor device.

17. The semiconductor package of claim 15, further comprising:
an upper vapor chamber on the vapor chamber; and
a heat pipe between the vapor chamber and the upper vapor chamber,
wherein the boiling enhancing layer is provided on an outer surface of the heat pipe.

18. The semiconductor package of claim 15, wherein the semiconductor device comprises:
an interposer substrate on the package substrate;
a first semiconductor chip mounted on the interposer substrate;
a second semiconductor chip mounted on the interposer substrate and separated from the first semiconductor chip; and
a molding layer disposed on the interposer substrate and surrounding the first semiconductor chip and the second semiconductor chip.

19. The semiconductor package of claim 18, wherein the boiling enhancing layer comprises a plurality of protruding patterns provided on the outer surface of the vapor chamber, and
wherein a first protruding pattern of the plurality of protruding patterns, in a first region vertically overlapping the first semiconductor chip, has a different shape than that of a second protruding pattern of the plurality of protruding patterns, in a second region vertically overlapping the second semiconductor chip.

20. A heat dissipation structure comprising:
a plurality of vapor chambers at different levels in a vertical direction; and
a plurality of heat pipes between the plurality of vapor chambers.

21. (canceled)

22. The heat dissipation structure of claim 20, wherein each vapor chamber of the plurality of vapor chambers comprises:
a chamber body providing an internal space in which a first working fluid flows; and
a first wick structure extending along an inner wall surface of the chamber body.

23.-27. (canceled)
